(19) United States
(12) Patent Application Publication
(10) Pub. No.: US 2013/0148284 A1
(43) Pub. Date: Jun. 13, 2013

(54) ELECTRONIC DEVICE WITH AIR DUCT

(71) Applicant: YAO-TING CHANG, Tu-Cheng (TW)

(72) Inventor: YAO-TING CHANG, Tu-Cheng (TW)

(73) Assignee: HON HAI PRECISION INDUSTRY CO., LTD., Tu-Cheng (TW)

(21) Appl. No.: 13/335,968

(22) Filed: Dec. 23, 2011

(30) Foreign Application Priority Data
Dec. 7, 2011 (TW) 100145002

(51) Int. Cl. G06F 1/20; H05K 7/20; G06F 1/16; F24F 13/02

(52) U.S. Cl. 361/679.31; 454/284; 361/695

(57) ABSTRACT

A air duct includes a top wall and two sidewalls extending down from two opposite sides of the top wall. A number of partition plates extend down from the top wall between and parallel to the sidewalls. Every adjacent two of the partition plates and the sidewalls cooperatively bound an airflow channel.

### BACKGROUND

1. Technical Field

The disclosure relates to electronic devices and, particularly, to an electronic device with an air duct for guiding airflow.

2. Description of Related Art

With the continuing development of electronic technology, components of electronic devices, such as central processing units (CPUs), memory cards, and the south bridge chips, generate a great deal of heat. The heat needs to be dissipated immediately to ensure the continued proper function of the electronic devices. Often, a cooling fan is provided to generate airflow, and an air duct is provided to guide the airflow. However, an ordinary air duct cannot adjust the airflow for different electronic components.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an isometric, exploded view of an embodiment of an electronic device, wherein the electronic device includes an air duct.

FIG. 2 is an inverted, enlarged view of the air duct of FIG. 1.

FIG. 3 is an assembled isometric view of FIG. 1.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

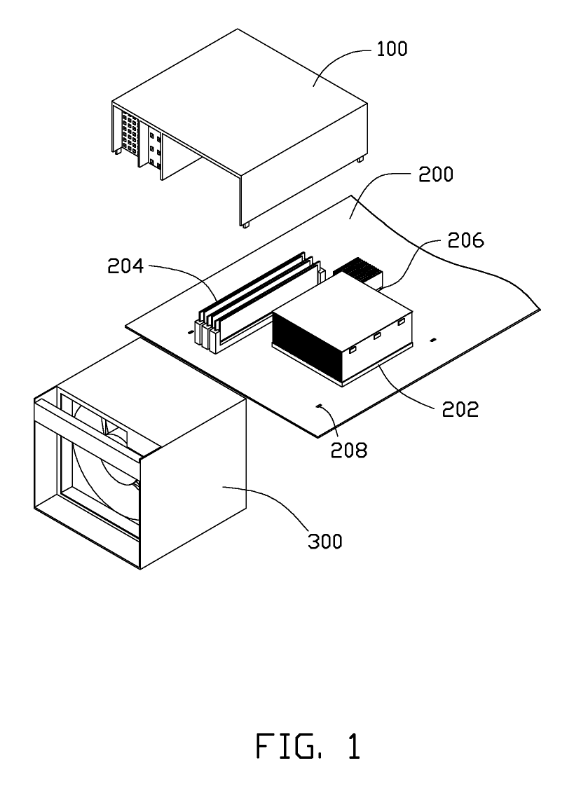

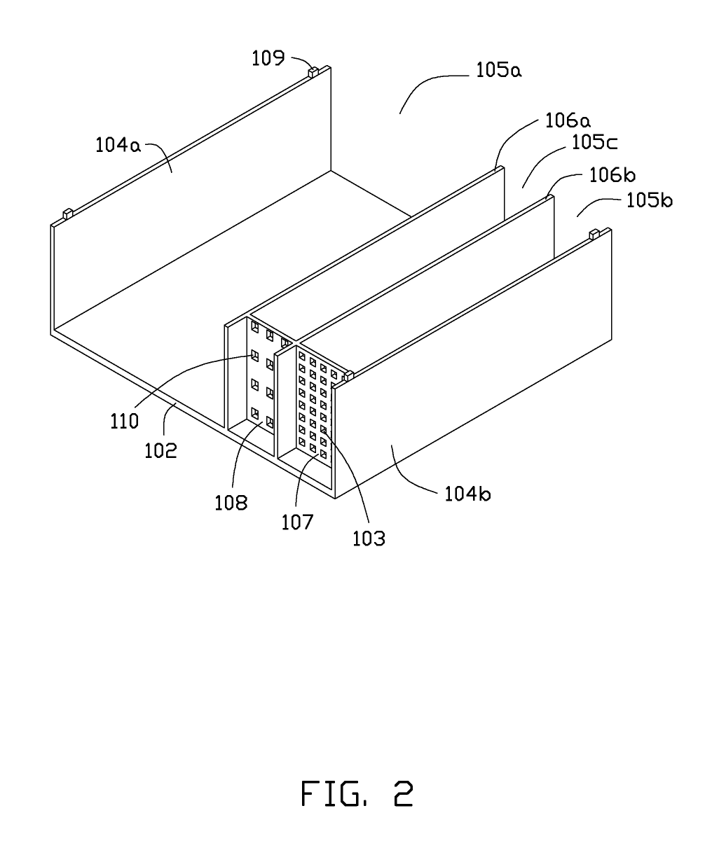

FIGS. 1 and 2, show an embodiment of an electronic device including an air duct 100, a motherboard 200, and a fan 300.

A first component 202, a second component 204, and a third component 206 are mounted on the motherboard 200. The third component 206 is located between and at a rear side of the first and second components 202 and 204. The motherboard 200 defines two fastening holes 208 in each of two opposite sides of the first and second components 202 and 204. In the embodiment, the first component 202 is a central processing unit (CPU), the second component 204 is a plurality of memory cards, and the third component 206 is a south bridge chip.

The fan 300 is fixed to a front side of the motherboard 200, with an air outlet of the fan 300 facing the first, second, and third components 202, 204, and 206.

The air duct 100 includes a top wall 102, two sidewalls 104a and 104b extending down from two opposite sides of the top wall 102, and two partition plates 106a and 106b extending down from the top wall 102 between and parallel to the sidewalls 104a and 104b. The partition plate 106a is adjacent to the sidewall 104a. The partition plate 106b is adjacent to the sidewall 104b. The sidewall 104a and the partition plate 106a cooperatively bound a first airflow channel 105a. The sidewall 104b and the partition plate 106b cooperatively bound a second airflow channel 105b. The partition plates 106a and 106b cooperatively bound a third airflow channel 105c. Ventilation flow of the first, second, and third airflow channels 105a, 105b, and 105c are decreased in that order. Which means a distance between the sidewall 104a and the partition plate 106a is larger than a distance between the sidewall 104b and the partition plate 106b, and the distance between the sidewall 104b and the partition plate 106b is larger than a distance between the partition plates 106a and 106b. Two tabs 109 protrude down from a bottom side of each of the sidewalls 104a and 104b.

In the embodiment, a first baffle 107 is perpendicularly fixed between the sidewall 104b and the partition plate 106b, and is located at a front end of the air duct 100. The first baffle 107 defines a plurality of vents 103. A second baffle 108 is perpendicularly fixed between the partition plates 106a and 106b, coplanar with the first baffle 107. The second baffle 108 defines a plurality of vents 110. The size of the vents 103 is less than the size of the vents 110, while the number of the vents 103 is greater than the number of the vents 110.

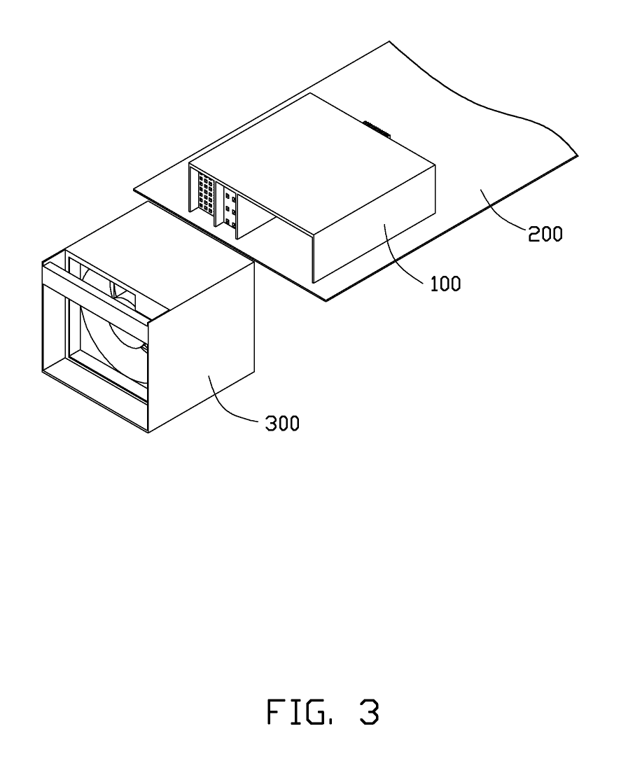

Referring to FIGS. 3, in assembly of the air duct 100 to the motherboard 200, the tabs 109 are inserted into the corresponding fastening holes 208. The first and second baffles 107 and 108 are adjacent to the fan 300. The first component 202 is positioned in the first airflow channel 105a. The second component 204 is positioned in the second airflow channel 105b. The third component 206 is positioned in the third airflow channel 105c. The first and second baffles 107 and 108 can adjust the airflow flowing through the second and third airflow channels 105b and 105c. The air flowing through the first, second, and third airflow channels 105a, 105b, and 105c is decreased in that order.

It is to be understood, however, that even though numerous characteristics and advantages of certain embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An air duct, comprising:
a top wall;
two sidewalls extending down from two opposite sides of the top wall; and
a plurality of partition plates extending down from the top wall between and parallel to the sidewalls, every adjacent two of the partition plates and the sidewalls cooperatively bound an airflow channel.

2. The air duct of claim 1, wherein each of the at least one of the air channels comprises a baffle fixed therein, and each baffle defines a plurality of vents.

3. The air duct of claim 1, wherein the number of the partition plates is two, one of the sidewalls and the adjacent partition plate cooperatively bound a first airflow channel, the other sidewall and the other partition plate cooperatively bound a second airflow channel, the partition plates cooperatively bound a third airflow channel.

4. The air duct of claim 3, wherein a first baffle is fixed at an end of the second airflow channel, a second baffle is fixed in the third airflow channel and adjacent to the first baffle, a plurality of first vents is defined in the first baffle, a plurality of second vents is defined in the second baffle.

5. The air duct of claim 4, wherein the size of the first vents is less than the size of the second vents, while the number of the first vents is larger than the number of the second vents.

6. An electronic device, comprising:
a motherboard comprising a plurality of components;
a fan aligning with the components; and
an air duct mounted on the motherboard, and comprising a plurality of airflow channels to respectively accommodate the components.

7. The electronic device of claim 6, wherein the air duct comprises a top wall, two sidewalls extending down from two opposite sides of the top wall, and a plurality of partition plates extending down from the top wall between and parallel to the sidewalls, each airflow channel is bounded by corresponding adjacent two of the partition plates and the sidewalls.

8. The electronic device of claim 7, wherein the number of the partition plates is two, one of the sidewalls and the adjacent partition plate cooperatively bound a first airflow channel, the other sidewall and the other partition plate cooperatively bound a second airflow channel, the partition plates cooperatively bound a third airflow channel, a first baffle is fixed at an end of the second airflow channel, a second baffle is fixed at the third airflow channel adjacent to the first baffle, the first and second baffles each defining a plurality of vents.

9. The electronic device of claim 8, wherein the components comprises a central processing unit positioned in the first airflow channel, a plurality of memory cards positioned in the second airflow channel, and a south bridge chip positioned in the third airflow channel.
